(19) United States
(12) Patent Application Publication
(10) Pub. No.: US 2009/0085231 A1
(43) Pub. Date: Apr. 2, 2009

(54) METHOD OF REDUCING MEMORY CARD EDGE ROUGHNESS BY PARTICLE BLASTING

(76) Inventors: Chin-Tien Chiu, Taichung City (TW); Chih Chiang Tung, Wu Chi Town (TW); Hem Takiar, Fremont, CA (US); Jack Chang Chien, Kaoshiung City (TW); Cheemen Yu, Madison, WI (US)

Correspondence Address: VIERRA MAGEN/SANDISK CORPORATION, 575 MARKET STREET, SUITE 2500, SAN FRANCISCO, CA, 94105, US

(21) Appl. No.: 11/864,125

(22) Filed: Sep. 28, 2007

(51) Int. Cl. H01L 23/28; H01L 21/00

(52) U.S. Cl. 257/787; 438/113; 257/E23.116

(57) ABSTRACT

A method of forming a semiconductor package with smooth edges, and a semiconductor package formed thereby is disclosed. In embodiments, after encapsulation, a panel of semiconductor packages may undergo a first cutting process which cuts the curvilinear edges of the packages. Next, the partially singulated panel of packages may undergo an abrasion process for smoothing the cut curvilinear edges. The abrasion process may occur by forcing abrasive particles over the jagged side edges of a semiconductor package as a result of a pressure differential above and below the semiconductor packages. Upon completion of the abrasive process, a second cutting process may be performed which cuts along straight edges and singulates the respective packages from the panel.

### BACKGROUND OF THE INVENTION

1. Field of the Invention

Embodiments of the present invention relate to methods of smoothing the edges of a portable memory card and a memory card formed thereby.

2. Description of the Related Art

As the sizes of electronic devices continue to decrease, the associated semiconductor packages that operate within them are being designed with smaller form factors, lower power requirements and higher functionality. Currently, sub-micron features in semiconductor fabrication are placing higher demands on package technology including higher lead counts, reduced lead pitch, minimum footprint area and significant overall volume reduction.

While a wide variety of packaging configurations are known, flash memory storage cards may in general be fabricated as system-in-a-package (SiP) or multichip modules (MCM), where a plurality of die are mounted on a substrate. The substrate may in general be a printed circuit board, a leadframe or a tape automated bonding (TAB) tape. FIG. 1 shows a cross-section of a plurality of semiconductor packages 20 being fabricated on a substrate panel 22. Semiconductor packages 20 are typically batch processed from panel 22 for economies of scale. Each package 20 includes one or more semiconductor die 24 mounted to the substrate, and electrical bond wires 26 for electrically coupling the one or more semiconductor die to the substrate. The substrate may further include passive components 28, such as for example capacitors, resistors and inductors further enabling the operation of the package 20. Where the packages 20 are LGA (land grid array) packages, such as are used in portable memory cards, contact fingers (not shown) may be formed on a surface of the substrate and coupled to the one or more semiconductor die through a lead pattern formed in the substrate. The contact fingers and lead pattern allow electrical communication between the semiconductor die in the package and a host device in which the package is used.

Once electrical connections between the die and substrate are made, the respective packages 20 on panel 22 may then typically be encapsulated in a molding compound to seal off and protect the components within the package. Once encapsulated, the respective packages 20 may be singulated from the panel 22 to form the finished packages. An example of a finished, encapsulated package is shown in prior art FIG. 2. The package 20 shown in FIG. 2 may for example be a TransFlash card, introduced by SanDisk Corporation of Sunnyvale, Calif., commonly used in cellular telephones and other mobile devices.

Many conventional semiconductor packages, like package 20 in FIG. 2, have both straight and curvilinear edges. The package 20 in FIG. 2 includes a generally rectangular shape having sides 32 through 38 joined by rounded corners. Side 32 of the package 20 further includes a notch 40 and an angled recessed section 42 defined in an upper portion of side 32 so that the top edge 34 of package 20 is narrower than the bottom edge 38 of the package 20. Many other types of memory cards similarly include a curvilinear shape having rounded edges, notches, and/or a chamfer.

Several methods are known for cutting the straight edges of a package 20 during singulation, including for example diamond saw. However, specialized cutting methods are required for cutting curvilinear shaped edges during singulation. Such specialized cutting methods include, for example, water jet cutting, laser cutting, water guided laser cutting, dry media cutting and diamond coated wire cutting. Such cutting methods are able to achieve sophisticated rectilinear and/or curvilinear shapes of the individualized integrated circuit packages. A more detailed description of methods for cutting encapsulated integrated circuits from a panel, and the shapes which may be achieved thereby, is disclosed in published U.S. Pat. No. 7,094,633, entitled “Method for Efficiently Producing Removable Peripheral Cards,” which patent is assigned to the owner of the present invention and which patent is incorporated by reference herein in its entirety.

As semiconductor packages continue to shrink, the structure within a host device for receiving and ejecting portable memory packages is becoming more delicate, and the ejection force with which smaller packages are ejected from the host device is getting smaller. Consequently, the roughness of the edges of portable memory packages is becoming a significant factor in package design, as small memory cards having rough edges may get stuck inside the host device.

Known cutting methods for cutting straight edges are effective at achieving smooth cuts. A measurement of roughness is Ra (average roughness), which is the measure of the average height of the bumps on a surface, measured for example in microns (μm). Straight edge cutting methods are typically able to achieve a roughness of Ra<1 μm. However, where a package includes curvilinear edges and is singulated by methods such as water jet or laser singulation, the edges are relatively more rough, typically about Ra=3 to 6 μm or greater. An example of a cut forming edges made by such methods is shown in prior art FIG. 3. FIG. 3 shows the packages 20 encapsulated in a mold compound 46 and including edges 50 defined by curvilinear cutting methods. As shown, the edges 50 of the package may be jagged, and may more easily get stuck within a host device. The cut made by curvilinear cutting methods also tends to get wider as it goes down through the packages during singulation. Thus, as shown in FIG. 3, the gap between edges 50 gets wider at a bottom surface 52 of the packages than at a top surface 54. While efforts are being made to improve curvilinear cutting methods, other solutions to the problem of rough package edges is needed.

### SUMMARY OF INVENTION

The present invention, roughly described, relates to a method of forming a semiconductor package with smooth edges, and a semiconductor package formed thereby. In embodiments, after encapsulation, a panel of semiconductor packages may undergo a first cutting process which cuts the curvilinear edges of the packages. Next, the partially singulated panel of packages may undergo an abrasion process for smoothing the cut curvilinear edges. Upon completion of the abrasion process, a second cutting process may be performed which cuts along straight edges to completely singulate the respective packages from the panel.

The abrasion process may be carried out within a process tool including one or more jigs for supporting one or more panels of partially singulated semiconductor packages. The jig includes slots sized and shaped to align with the cut edges of the semiconductor packages of the panel. Once positioned on a jig within the process tool, small abrasive particles, such as for example garnets, may be supplied into the tool in an area on top of the respective semiconductor packages. The area may be filled with a fluid such as air, and may be maintained, for example, at ambient pressure.

A vacuum or low pressure area may then be created within the process tool in an area beneath the jig. This creates a pressure differential above and below the jig, and the abrasive particles are pulled down along the edges and through the slots to the lower vacuum area. The flow of the abrasive particles over time will accomplish two functions. First, the particles will smooth the jagged edges of the semiconductor packages. Second, the particles will create smooth, rounded radius edges between the top surfaces and side edges of the respective semiconductor packages. In accordance with the present invention, the abrasive particles advantageously smooth the side edges of the semiconductor packages, while leaving other surfaces, such as the top surfaces of packages, unaffected.

The particles may be evacuated from the process tool by a vacuum generator, which in turn passes the particles to a filter and recycle tank which separates the particles from particulates generated from the abrasion process. Thus, the particles may be recycled back into the process tool continuously.

### BRIEF DESCRIPTION OF THE DRAWINGS

FIG. 1 is a side view of a plurality of integrated circuits formed on a substrate panel according to the prior art.

FIG. 2 is a top view of a singulated semiconductor package according to the prior art.

FIG. 3 is a side view of a plurality of singulated semiconductor packages including rough edges formed by certain cutting processes of the prior art.

FIG. 4 is a top view of a panel of semiconductor packages including curvilinear cuts partially singulating the packages from the panel.

FIG. 5 is a side view of a pair of semiconductor packages seated on a jig according to embodiments of the present invention.

FIG. 6 is a side view of a pair of semiconductor packages seated on a jig and including abrasive particles introduced over an upper surface of the packages.

FIG. 7 is a side view of a pair of semiconductor packages having edges smoothed by abrasive particles flowing past the edges as a result of a pressure differential above and below the packages.

FIG. 8 is a top view of a single semiconductor package after the abrasion process.

FIG. 9 is a top view of a semiconductor package after straight edge cuts are made to fully singulate the package from the panel.

FIG. 10 is a schematic representation of a system for performing embodiments of the present invention.

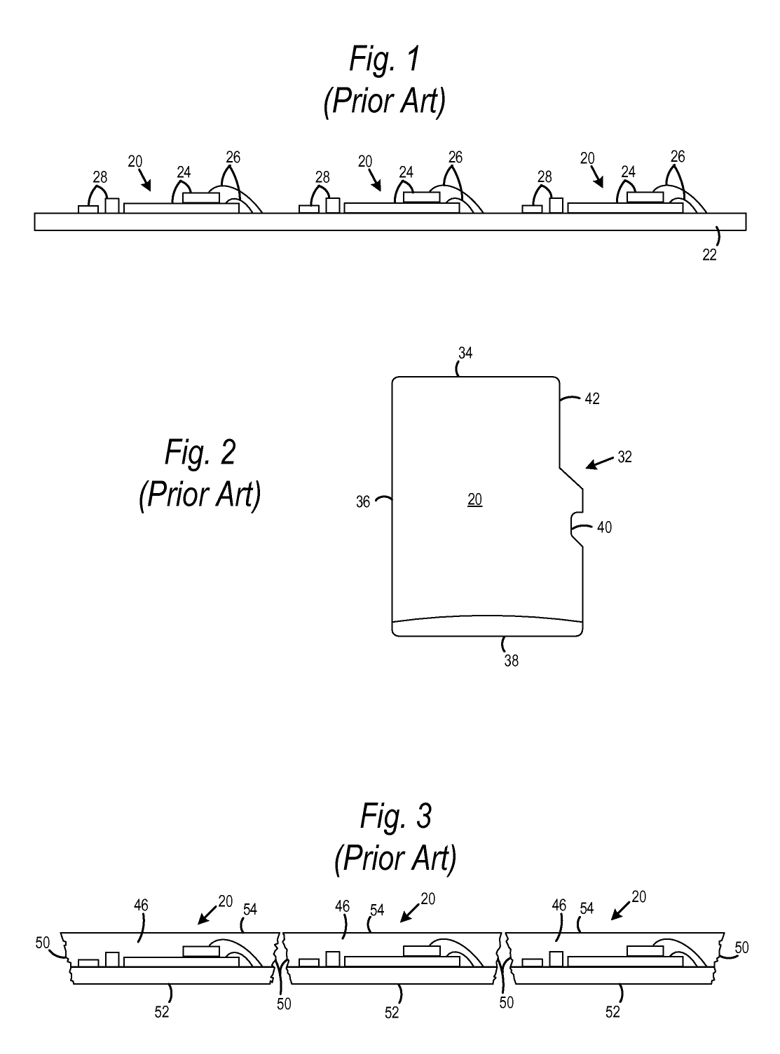

### DETAILED DESCRIPTION

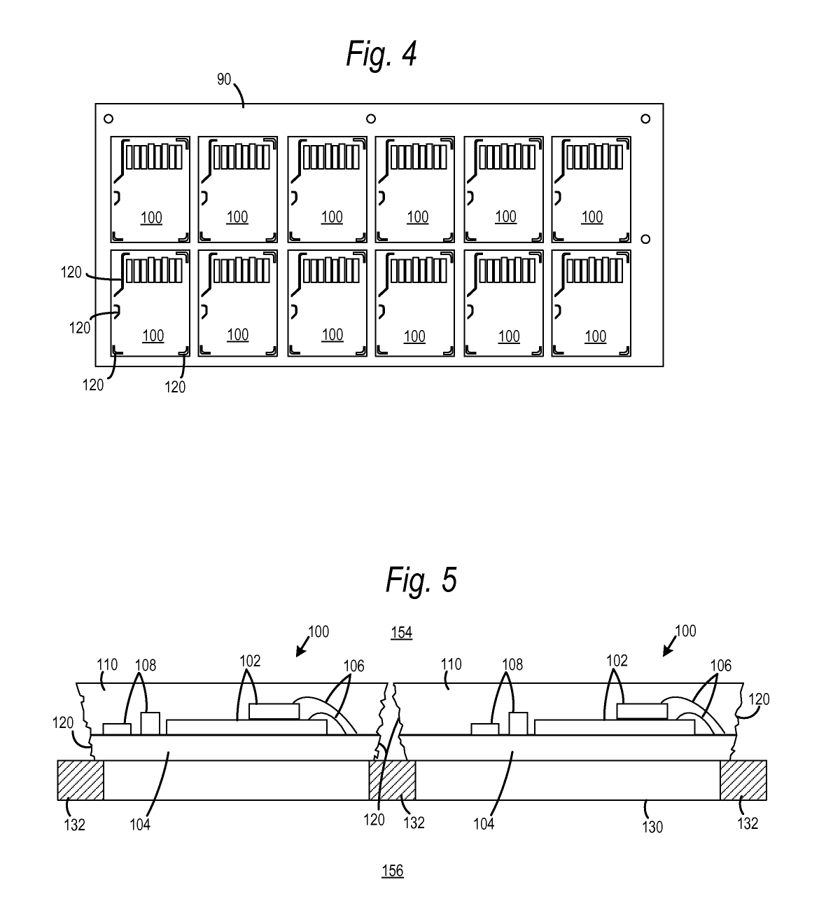

The embodiments of the present invention will now be described with reference to FIGS. 4 through 10, which generally relate to a method of forming a semiconductor package with smooth edges, and a semiconductor package formed thereby. It is understood that the present invention may be embodied in many different forms and should not be construed to being limited to the embodiments set forth herein. Rather, these embodiments are provided so that this disclosure will be thorough and complete and will fully convey embodiments of the invention to those skilled in the art. Indeed, the invention is intended to cover alternatives, modifications and equivalents of these embodiments, which are included within the scope and spirit of the invention as defined by the appended claims. Furthermore, in the following detailed description of embodiments of the present invention, numerous specific details are set forth in order to provide a thorough understanding of the present invention. However, it will be clear to those with ordinary skill in the art that the present invention may be practiced without such specific details.

Referring initially to the top view of FIG. 4, in general, semiconductor packages according to the present invention may be batch processed from a panel 90 including a plurality of semiconductor packages 100 formed thereon for economies of scale. FIG. 4 shows a two dimensional array of semiconductor packages 100, but it is understood that the panel from which packages 100 are formed may include varying numbers of packages across the length and/or width of the panel.

FIG. 5 shows a side view of two packages 100 from panel 90. The composition and method of fabrication of the respective semiconductor packages 100 may vary greatly in alternative embodiments. In one embodiment, each package 100 may include one or more semiconductor die 102 mounted to a substrate 104. Although not critical to the present invention, the die 102 may include one or more flash memory chips, and possibly a controller such as an ASIC, so that the package 100 may be used as a flash memory device. It is understood that the package 100 may include semiconductor die configured to perform other functions in further embodiments of the present invention.

Although not critical to the present invention, substrate 104 may be a variety of different chip carrier mediums, including a PCB, a leadframe or a TAB tape. Where substrate 104 is a PCB, the substrate may be formed of a core having top and/or bottom conductive layers formed thereon. The core may be various dielectric materials such as for example, polyimide laminates, epoxy resins including FR4 and FR5, bismaleimide triazine (BT), and the like. The conductive layers may be formed of copper or copper alloys, plated copper or plated copper alloys, Alloy 42 (42FE/58NI), copper plated steel or other metals or materials known for use on substrates. The conductive layers may be etched into a conductance pattern as is known for communicating signals between the semiconductor die and an external device. A dummy pattern may also be provided in the conductive layers as is known to reduce mechanical stresses on the substrate otherwise resulting from uneven thermal expansion within the substrate. Substrate 104 may additionally include exposed metal portions forming contact pads (not shown) for receiving wire bonds and/or contact fingers (not shown) where the package 100 is an LGA package. The contact pads and/or fingers may be plated with one or more gold layers, for example in an electroplating process as is known in the art.

Where substrate 104 is a leadframe, the leadframe may be formed of a planar or substantially planar piece of metal, such as copper or copper alloys, plated copper or plated copper alloys, Alloy 42 (42Fe/58Ni), or copper plated steel. The leadframe may also be plated with silver, gold, nickel palladium, or copper. The individual leads for bonding to die 102 may be formed by photolithographic processes or mechanical stamping.

The semiconductor die 102 may be bonded to the substrate 104 in a known die bond process. After die 102 are affixed to substrate 104, wires bond 106 may be attached between bond pads on die 100 and bond pads on substrate 104. Wire bonds 106 may be affixed in a known wire bonding process and may be provided along a single side, or along two, three or four sides of die 102 and substrate 104. The package 100 may further include passive components 108, such as for example capacitors, resistors and inductors further enabling the operation of the package 100.

Once electrical connections between the die and substrate are made, the respective packages 100 may then typically be encapsulated in a molding compound 110 to seal off and protect the components within the package. Molding compound 110 may be a known epoxy such as for example available from Sumitomo Corp. and Nitto Denko Corp., both having headquarters in Japan.

After encapsulation, semiconductor packages of the prior art are typically singulated from the panel. As explained in the Background section and as shown in prior art FIG. 2, some packages 100 may not be rectangular in shape, but may include a variety of curvilinear edges defining for example rounded corners, obliquely connecting sections, notches, chamfers, etc. As further explained in the Background section, cutting methods for making curvilinear cuts may result in jagged edges, such as edges 120 shown in FIGS. 4 and 5 (the edges 120 are labeled on only one package 100 in FIG. 4, but all packages 100 may include jagged edges 120). In accordance with the present invention, the packages 100 may undergo a first cutting process which cuts the curvilinear edges of a package, an abrasion process for smoothing the cut curvilinear edges, and then a second cutting process which cuts along straight edges and singulates the respective packages from the panel.

In the first cutting process, the curvilinear edges of the semiconductor package 100 may be cut by any of a variety of known cutting processes such as water jet cutting or laser cutting. At this point, the respective semiconductor packages are only partially cut and remain in position, fastened to the panel. The result of one embodiment of the first cutting process is shown in FIG. 4.

After the curvilinear edges are cut, the panel may be transferred into a process tool 200, explained in greater detail below. Within process tool 200, the panel of partially singulated semiconductor packages may be supported on a jig 130 as shown in FIGS. 5-7. The respective packages are aligned on jig 130 so that the cut edges 120 of the respective packages on the panel are positioned over slots 132 formed through the surface of jig 130. In embodiments, the jig 130 may be configured for the particular type of package being formed, so that the slots 132 conform in shape and position with all curvilinear edges 120 cut in the first cutting process. In alternative embodiments, only some of the cut curvilinear edges 120 may be positioned over a slot 132, with other cut curvilinear edges resting over a solid portion of the jig 130. In such embodiments, only those sections resting over slots will be smoothed as explained hereinafter. For example, it may be determined that only certain curvilinear edges are prone to catching within a host device. In this alternative embodiment, only those edges which are prone to catching may be smoothed. However, as indicated above, it may be that the slots align with all cut edges 120 and that all cut edges are smoothed.

The present invention may be advantageously used for smoothing edges formed by cutting processes which create relatively rough edges, such as for example curvilinear edges formed by water jet cutting and laser cutting. However, it is understood that the process of the present invention may be used to smooth any semiconductor package edge, straight or curvilinear, regardless of the cutting method used to cut the edge. Thus, while an embodiment of the present invention operates by first cutting the curvilinear edges, smoothing the cut edges as explained below, and then completing the singulation by then cutting the straight edges, it is understood that both curvilinear edges and straight edges may be cut in the first cutting process in alternative embodiments. In such alternative embodiments, a portion of each semiconductor package may remain uncut (preferably a portion which does not require smoothing). Thus, the packages would remain affixed to the panel when the panel is placed within the tool 200 for smoothing. In such embodiments, all cut edges may be positioned over aligned slots and smoothed. Alternatively in this embodiment, only certain cut edges may be smoothed. For example, at least some of the straight edges cut with a diamond saw may not be smoothed.

In a further embodiment, the packages 100 may be completely singulated from the panel in the first cutting process. In such embodiments, the packages may be aligned individually on jig 130 in process tool 200. Thereafter, some or all of the edges of each package may be smoothed as explained below.

The slots 132 may have a diameter of between 10 and 50 μm, and more particularly between 20 and 40 μm. It is understood that the slots 132 may be wider or narrower than these ranges in alternative embodiments. In the embodiment shown in FIGS. 4-7, two edges 120 lie adjacent to each other over a slot 132 as a result of a cut. However, it is further contemplated that one or more cuts may be made resulting in the removal of a piece of the panel adjacent a semiconductor package. In such instances, only a single edge 120 may lie over a slot 132.

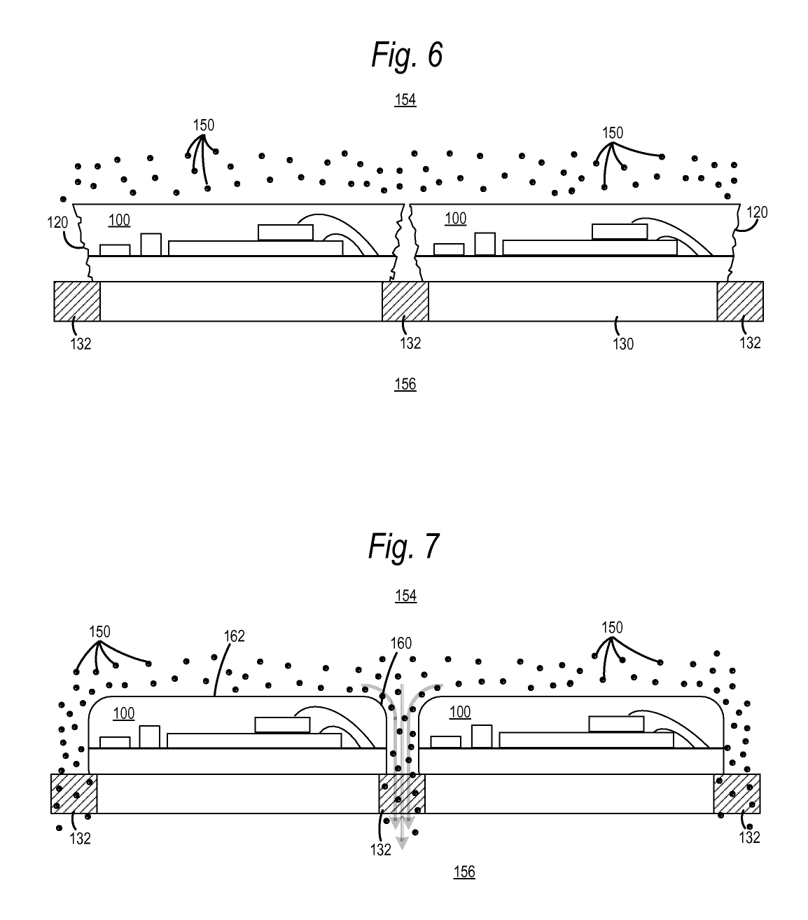

Referring now to FIG. 6, there is shown a pair of semiconductor packages 100 from panel 90 supported on jig 130. In accordance with the present invention, particles 150 may be supplied into the tool 200 in an area 154 on top of the respective semiconductor packages 100. Area 154 may be filled with a fluid such as air, or an inert gas such as argon, and may be maintained, for example, at ambient pressure. Particles 150 may be a silicate or other type of mineral or material, such as for example garnets. In an alternative embodiment, the fluid within area 154 may be a liquid slurry including particles 150. Each particle may be fine grain, having a size of approximately 10 to 50 μm, but it is understood that particles 150 may be larger or smaller than that in alternative embodiments of the present invention.

Once packages 100 are positioned on jig 130 with one or more edges 120 aligned over slots 132, a vacuum or low pressure area may be created within tool 200 in an area 156 beneath jig 130. As shown in FIG. 7, this creates a pressure differential between areas 154 and 156 above and below, respectively, jig 130. This pressure differential pulls particles 150 down along edges 120 and through slots 132 to vacuum area 156. Particles 150 may be pulled through all slots 132 in jig 130 and across all edges 120 aligned along such slots 132.

Particles 150 are an abrasive which over time accomplishes at least two functions. First, the particles 150 will smooth jagged edges 120 as shown in FIG. 7. That is, the particles 150 will abrade the molding compound 110 and the exposed edges of substrate 104 to reduce the roughness of edges 120. A second, independent function of abrasive particles 150 is to create smooth, rounded radius edges 160 between the top surface 162 of the respective semiconductor packages 100 and the side edges 120 of the respective semiconductor packages 100.

In accordance with the present invention, the particles 150 advantageously smooth edges 120 of packages 100, while leaving other surfaces, such as surfaces 162 of packages 100 unaffected. This is because flow rate, Q, is defined by the product of the cross sectional area multiplied by the velocity over that area. The area occupied by particles 150 above surfaces 162 of packages 100 is relatively large. Thus, for a given flow rate created by the pressure differential, the velocity of particles 150 above and adjacent to surfaces 162 is relatively small. The low velocity of particles 150 above surfaces 162 imparts a relatively small kinetic energy to each of the particles, thus preventing the particles from abrading or appreciably abrading surfaces 162.

However, the cross sectional area between adjacent edges 120 of adjacent semiconductor packages 100 is relatively small. The distance between adjacent edges 120 may be no more than the width of the cut, and may for example be 50 to 100 μm. Accordingly, for the same flow rate Q, as particles 150 pass through the relatively narrow cross sectional area between adjacent semiconductor packages, the velocity of the particles 150 increases significantly as they pass along edges 120 and down through slots 132. The high speed of the moving particles creates high kinetic energy enabling the particles 150 to abrade edges 120 to create smooth edges. Moreover, the velocity of the particles 150 increases as they approach and enter the space between adjacent edges 120, thus creating the smooth radius corner. It is understood that the particles 150 may achieve high velocities and kinetic energies for abrading edges 120 by mechanisms other than having a narrow space between a pair of edges 120.

The degree of roughness of edges 120 after processing as described above may vary depending on a variety of factors. These factors include the size and shape of particles 150, the density of the particles within the tool 200, the pressure differential between the upper and lower regions of tool 200, and the length of time which the packages 100 are exposed to the pressure differential and abrasive particles 150. In embodiments, edges 120 may be processed to have a roughness, Ra, of less than 1 μm.

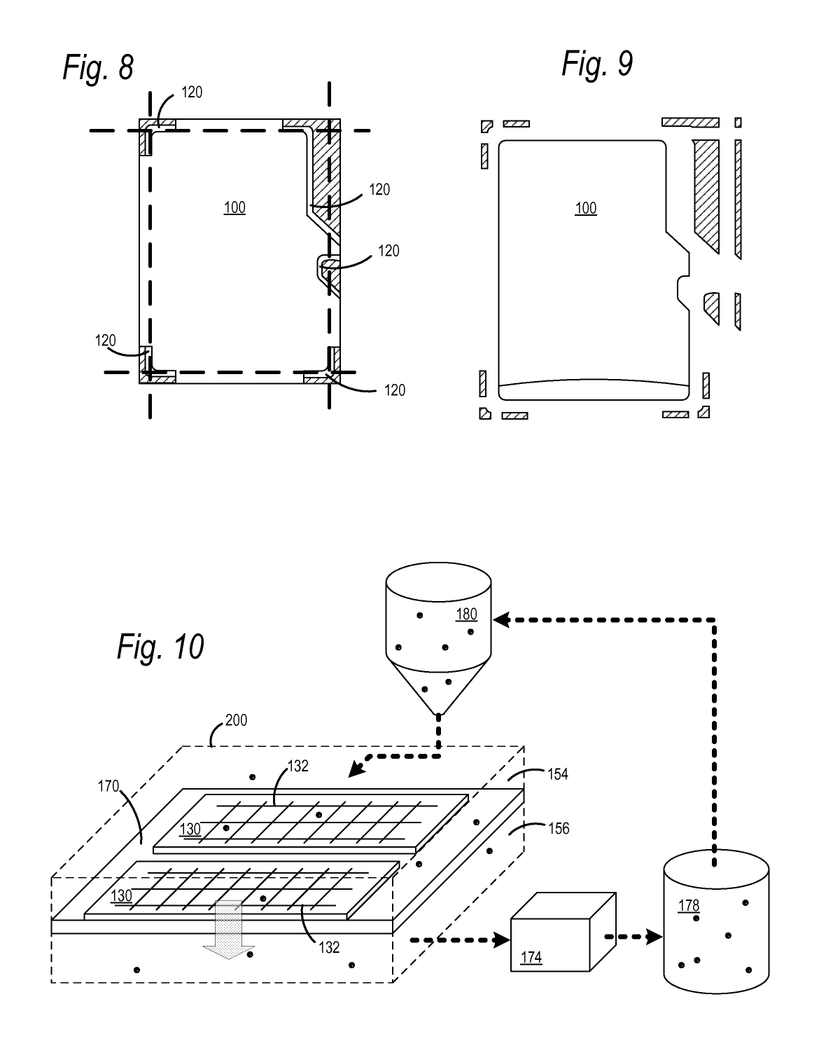

Referring now to FIGS. 8 and 9, after the edges 120 have been abraded and smoothed as described above, the respective semiconductor packages 100 may be completely singulated from panel 90, for example by performing straight cuts with a diamond saw blade. The result is a finished semiconductor package 100 including smooth edges and radiused corners between the top surface and side edges. The bottom surface of substrate 104 may be unaffected by particles 150 as the bottom surface lies in contact with jig 130 while the particles 150 are abrading edges 120.

The package 100 shown in FIGS. 8 and 9 may be a Transflash card. However, it is understood that the present invention may be used for a variety of other semiconductor devices having curvilinear and/or straight edges, including for example SD cards and Micro SD cards. Other devices are contemplated.

FIG. 10 shows a schematic representation of a system for performing the process of the present invention. The system may include the process tool 200 within which one or more jigs 130 may be housed. FIG. 10 shows two such jigs 130, however, the tool 200 may have room for a single jig or greater than two jigs in further embodiments. Each jig 130 may support one or more panels of semiconductor packages 100. Alternatively, a jig 130 may be configured to receive semiconductor packages that are not in a panel. It is also contemplated that packages from different panels may be positioned adjacent to each other on a jig 130.

As explained above, tool 200 may include a lower region 156 capable of having a vacuum or a lower pressure than an upper region 154. In embodiments, the only openings joining regions 154 and 156 is through slots 132 in jigs 130. In embodiments, the one or more jigs 130 within tool 200 may be seated on a table 170 within tool 200 effectively sealing off region 154 from region 156 except at slots 132. Alternatively, table 170 may be omitted, and the one or more jigs 130 themselves extend to the boundaries of the tool 200 to effectively seal off region 154 from region 156 except at slots 132.

Low pressure region 156 may be connected to a vacuum generator 174 external to tool 200. Vacuum generator 174 may be a pump or mechanism of known construction capable of drawing fluid and particles out of region 156 to create the vacuum within region 156 and the pressure differential within tool 200. The vacuum generator 174 may pump fluid and particles 150 to a filter and recycle tank 178. Filter and recycle tank 178 may use a known filtration scheme for separating the particles 150 from any particulate which may be generated during the abrading process. Thus, the particles 150 may be recycled back into tool 200 continuously.

The recycled particles 150 may be transferred from filter and recycle tank 178 to a particle supply store 180, for example by one or more pumps within or external to tank 178 and/or store 180. Store 180 may in turn be connected to process tool 200 and may supply particles 150 to ambient pressure region 156, where the particles 150 may then again be pulled down through slots 132 to vacuum region 156. In this way, particles 150 may continuously be regenerated for use within process tool 200 to smooth the edges of semiconductor packages 100. It is contemplated that from time to time the particles 150 may be replaced by new particles, either exchanging old for new particles all at once, or exchanging new for old particles gradually a little at a time.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of fabricating a semiconductor package on a panel, comprising the steps of:
(a) encapsulating at least one semiconductor die and at least part of a substrate in a molding compound;
(b) at least partially singulating the semiconductor package from the panel by making one or more cuts through the panel to define an edge in the semiconductor package; and
(c) abrading the edge of the semiconductor package formed in said step (b) by a plurality of abrasive particles pulled across the edge by a pressure differential above and below the edge.

2. A method as recited in claim 1, wherein said step (b) of at least partially singulating the semiconductor package from the panel by making one or more cuts through the panel comprises the step of making one or more curvilinear cuts.

3. A method as recited in claim 2, wherein said step (c) of abrading an edge of the semiconductor package defined by a cut of the one or more cuts comprises the step of abrading a curvilinear cut.

4. A method as recited in claim 1, wherein in said step (b) of at least partially singulating the semiconductor package from the panel by making one or more cuts through the panel comprises the step of making one or more cuts by one of laser cutting and water jet cutting.

5. A method as recited in claim 4, wherein said step (c) of abrading an edge of the semiconductor package defined by a cut of the one or more cuts comprises the step of abrading the cut made by one of laser cutting and water jet cutting.

6. A method as recited in claim 1, wherein said step (b) comprises partially singulating the semiconductor package from the panel, the method further comprising the step (d) of making one or more additional cuts through the substrate after said step (c) to singulate the package from the panel.

7. A method as recited in claim 1, wherein said step (c) of abrading an edge of the semiconductor package comprises the step of abrading the edge to a roughness of less than or equal to 1 micron.

8. A method as recited in claim 1, further comprising the step (e) of forming a rounded corner between the edge formed in said step (b) and a top surface of the semiconductor package.

9. A method as recited in claim 1, wherein said step (c) of abrading an edge of the semiconductor package by a plurality of abrasive particles comprises the step of abrading the edge with silicate particles.

10. A method as recited in claim 1, wherein said step (c) of abrading an edge of the semiconductor package by a plurality of abrasive particles comprises the step of abrading the edge with garnets.

11. A method as recited in claim 1, further comprising a step (f) of recycling the particles for said step (c) of abrading the edge of the semiconductor package.

12. A method of fabricating a semiconductor package on a panel, comprising the steps of:
(a) encapsulating at least one semiconductor die and at least part of a substrate in a molding compound;
(b) partially singulating the semiconductor package from the panel by making one or more cuts through the panel to define an edge in the semiconductor package; and
(c) abrading the edge of the semiconductor package formed in said step (b) by a plurality of abrasive particles contacting the edge.

13. A method as recited in claim 12, wherein said step (b) of at least partially singulating the semiconductor package from the panel by making one or more cuts through the panel comprises the step of making one or more curvilinear cuts.

14. A method as recited in claim 13, wherein said step (c) of abrading an edge of the semiconductor package defined by a cut of the one or more cuts comprises the step of abrading a curvilinear cut.

15. A method as recited in claim 12, further comprising the step (d) of making one or more additional cuts through the substrate after said step (c) to singulate the package from the panel.

16. A method as recited in claim 12, wherein said step (c) of abrading an edge of the semiconductor package defined by a cut of the one or more cuts comprises the step of abrading the edge to a roughness of less than or equal to 1 micron.

17. A method as recited in claim 12, further comprising the step of forming a rounded corner between the edge formed in said step (b) and a top surface of the semiconductor package.

18. A method as recited in claim 12, wherein said step (c) of abrading an edge of the semiconductor package by a plurality of abrasive particles comprises the step of abrading the edge with silicate particles.

19. A method as recited in claim 12, wherein said step (c) of abrading an edge of the semiconductor package by a plurality of abrasive particles comprises the step of abrading the edge with garnets.

20. A method as recited in claim 12, wherein said step (c) of abrading an edge of the semiconductor package by a plurality of abrasive particles comprises the step of abrading the edge with particles having a size of between 10 microns and 50 microns.

21. A method as recited in claim 12, wherein said step (c) of abrading an edge of the semiconductor package by a plurality of abrasive particles comprises the step of abrading the edge with particles pulled over the edge due to a pressure differential above and below the edge.

22. A method of fabricating a semiconductor package on a panel, comprising the steps of:
(a) encapsulating at least one semiconductor die and at least part of a substrate in a molding compound;
(b) making a set of one or more curvilinear cuts through the panel to define one or more edges in the semiconductor package;
(c) abrading the edge of the semiconductor package formed in said step (b) by a plurality of abrasive particles pulled across the edge by a pressure differential above and below the edge; and
(d) making a second set of one or more straight cuts, after said step (c), to singulate the semiconductor package from the panel.

23. A method as recited in claim 22, wherein said step (b) of making a set of one or more curvilinear cuts through the panel comprises the step of making one or more cuts by one of laser cutting and water jet cutting.

24. A method as recited in claim 22, wherein said step (d) of making a second set of one or more straight cuts comprises the step of making one or more cuts by a blade sawing through the panel.

25. A method as recited in claim 22, wherein said step (c) of abrading an edge of the semiconductor package comprises the step of abrading the edge to a roughness of less than or equal to 1 micron.

26. A method of fabricating a semiconductor package on a panel, comprising the steps of:
(a) encapsulating at least one semiconductor die and at least part of a substrate in a molding compound;
(b) making a set of one or more curvilinear cuts through the panel to define one or more edges in the semiconductor package;
(c) positioning the panel within a tool, on a jig including a plurality of slots aligned with the one or more edges in the semiconductor package;
(d) supplying abrasive particles within the tool;
(e) creating a pressure differential above and below the edge and slot, the pressure differential pulling the abrasive particles across the edge and through the slot to smooth the edge; and
(f) making a second set of one or more straight cuts, after said step (e), to singulate the semiconductor package from the panel.

27. A method as recited in claim 26, further comprising the step (g) of recirculating the abrasive particles back into the tool after the abrasive particles have been drawn out of the tool by the pressure differential.

28. A method as recited in claim 27, further comprising the step (h) of filtering particulates away from the particles prior to said step (g) of recirculating the abrasive particles back into the tool.

29. A method as recited in claim 26, further comprising the step of filling the tool with air, the step (e) of creating the pressure differential pulling the air through the slots.

30. A method as recited in claim 26, wherein in said step (b) of making a set of one or more curvilinear cuts through the panel comprises the step of making one or more cuts by one of laser cutting and water jet cutting.

31. A method as recited in claim 26, wherein said step (e) of creating a pressure differential pulling the abrasive particles across the edge comprises the step of abrading the edge to a roughness of less than or equal to 1 micron.

32. A method as recited in claim 26, further comprising the step (k) of forming a rounded corner between the edge formed in said step (b) and a top surface of the semiconductor package.

33. A method as recited in claim 26, wherein said step (d) of supplying abrasive particles within the tool comprises the step of supplying garnets within the tool.

34. A semiconductor package, comprising:
a substrate;
one or more semiconductor die electrically coupled to the substrate;
molding compound encapsulating the one or more semiconductor die and at least a portion of the substrate, at least one of the substrate and molding compound defining an upper surface of the package, a lower surface of the package and one or more edges extending between the upper and lower surfaces of the package;
the package formed by the steps of:
(a) encapsulating the one or more semiconductor die and at least part of a substrate in a molding compound;
(b) at least partially singulating the semiconductor package from a panel by making one or more cuts through the panel to define an edge of the one or more edges in the semiconductor package; and
(c) abrading the edge of the semiconductor package formed in said step (b) by a plurality of abrasive particles pulled across the edge by a pressure differential above and below the edge.

35. A semiconductor package as recited in claim 34, wherein said step (b) of at least partially singulating the semiconductor package from the panel by making one or more cuts through the panel comprises the step of making one or more curvilinear cuts.

36. A semiconductor package as recited in claim 34, wherein in said step (b) of at least partially singulating the semiconductor package from the panel by making one or more cuts through the panel comprises the step of making one or more cuts by one of laser cutting and water jet cutting.

37. A semiconductor package as recited in claim 34, wherein said step (b) comprises partially singulating the semiconductor package from the panel, the method further comprising the step (d) of making one or more additional cuts through the substrate after said step (c) to singulate the package from the panel.

38. A semiconductor package as recited in claim 34, wherein said step (c) of abrading an edge of the semiconductor package comprises the step of abrading the edge to a roughness of less than or equal to 1 micron.

39. A semiconductor package as recited in claim 34, further comprising the step (e) of forming a rounded corner between the edge formed in said step (b) and the top surface of the semiconductor package.

40. A semiconductor package as recited in claim 34, wherein said step (c) of abrading an edge of the semiconductor package by a plurality of abrasive particles comprises the step of abrading the edge with silicate particles.

41. A semiconductor package as recited in claim 34, wherein said step (c) of abrading an edge of the semiconductor package by a plurality of abrasive particles comprises the step of abrading the edge with garnets.

42. A semiconductor package as recited in claim 34, further comprising a step (f) of recycling the particles for said step (c) of abrading the edge of the semiconductor package.
